(19) United States
(12) Patent Application Publication
(10) Pub. No.: US 2005/0032320 A1
(43) Pub. Date: Feb. 10, 2005

(54) Method for manufacturing a semiconductor device and a semiconductor device manufactured thereby

(76) Inventor: Takashi Yokoyama, Kanagawa (JP)

Correspondence Address: ROBERT J. DEPKE LEWIS T. STEADMAN;HOLLAND & KNIGHT LLC, 131 SOUTH DEARBORN, 30TH FLOOR, CHICAGO, IL, 60603, US

(21) Appl. No.: 10/910,992

(22) Filed: Aug. 4, 2004

(30) Foreign Application Priority Data
Aug. 7, 2003 (JP) JP2003-288417
Aug. 29, 2003 (JP) JP2003-305926

(51) Int. Cl. H01L 21/8234

(52) U.S. Cl. 438/296; 438/629

(57) ABSTRACT

A method for manufacturing a semiconductor device is provided, which is consisting of the steps of: forming a transistor on a surface region of a semiconductor substrate which is isolated by an insulating isolation region; forming an inter-layer insulation film provide with a hydrogen supplying path that reaches said isolation region on said semiconductor substrate on which said transistor is formed; and supplying hydrogen in said semiconductor substrate from said hydrogen supplying path through said isolation region by carrying out heat treatment. And also the semiconductor device is provided manufactured thereby.

### BACKGROUND OF THE INVENTION

1. Field of the Invention

The present invention relates to a method for manufacturing a semiconductor device and a semiconductor device manufactured by the method, and particularly relates to a method for manufacturing a semiconductor device having a MOS transistor, in which damage caused by hydrogen termination on a channel portion boundary is easily recovered, and to a semiconductor device manufactured by the method.

2. Description of the Related Art

In association with the hyperfine structure of a design rule in a semiconductor device, in a device whose technology node is below 65 nm, the reservation of the reliability of a transistor becomes more and more difficult. In particular, in the semiconductor device whose high integration is progressed, the passage through various processes in device integration causes damage to be inflicted on silicon near a channel, which brings about the variation in a threshold voltage and the increase in a leak current (Ioff). For this reason, in manufacturing of a semiconductor device, a hydrogen annealing process is carried out at the final step. Consequently, the silicon dangling bond near the channel, which is induced in the manufacturing step, is hydrogen-terminated, and a damage recovering process is performed on silicon near the channel portion.

Also, a method is also proposed which forms an inter-layer insulation film containing hydrogen, that covers transistor, and forms a surface protecting film on this inter-layer insulation film, and then carries out a heat treatment, and consequently diffuses the hydrogen in the inter-layer insulation film into the channel portion and accordingly carries out the above-mentioned damage recovering process. (refer to the following Patent Document 1).

### Patent Document 1

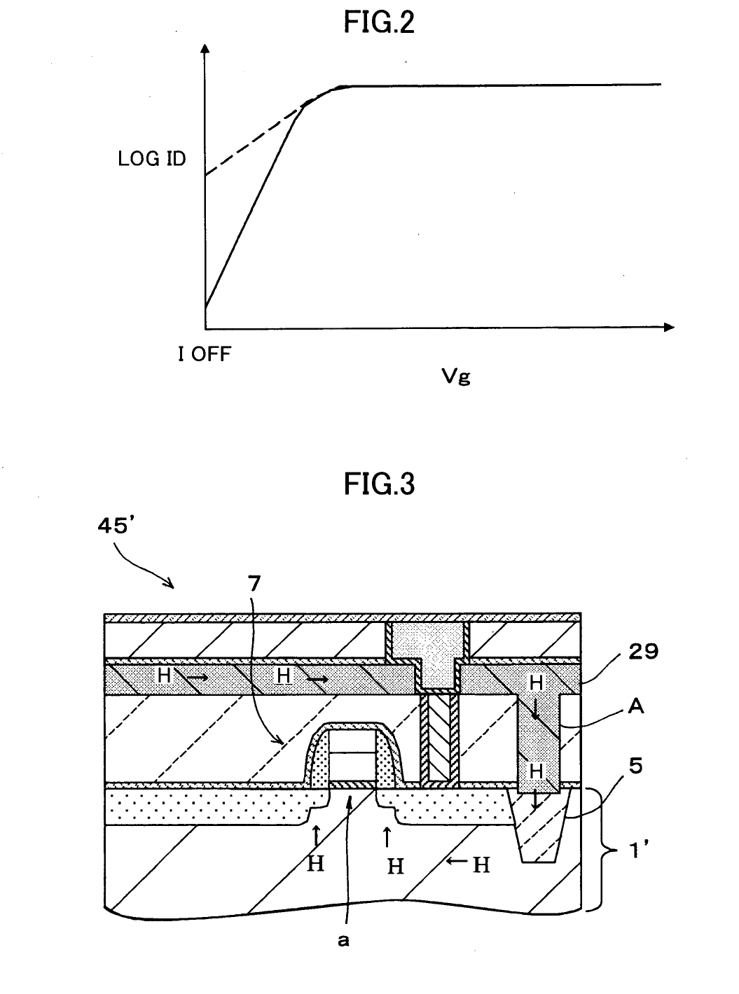

Japanese Patent Application Publication No. (JP-A, 2000-252277) (in particular, FIG. 2 and 0034 to 0036)

However, because of the higher integration of the semiconductor device, although the interconnect layer formed on a substrate tends to be multileveled, the tendency of the thinner interconnect layer film is little. Thus, because of the advancement of the higher integration, the film thickness of the total inter-layer insulation films tends to be increased. Also, when copper (Cu) is used for the interconnect, etching stopper layer and diffusion protecting film that are composed of silicon nitride film, through which hydrogen is difficult to pass, or the like are used in a part of the inter-layer insulation film. For this reason, in the method in which the hydrogen annealing process is carried out at the final step, it is difficult to make the hydrogen arrive at the vicinity of the channel of the transistor, and it becomes difficult to recover the damage of the channel portion.

The method of forming an inter-layer insulation film containing the hydrogen, which covers the transistor, can effectively diffuse the hydrogen into the silicon substrate, by forming the inter-layer insulation film containing the hydrogen, below the film such as the silicon nitride film through which the hydrogen is not transmitted. However, in manufacturing the semiconductor device that is further multileveled, even if the inter-layer insulation film is formed at the initial stage, the hydrogen are dissociated or separated from the inter-layer insulation film, for example, at a high temperature processing of forming a contact plug or the like. Thus, in the heat treatment at the final step, it is impossible to sufficiently supply the hydrogen. Hence, it is difficult to effectively recover the damage in the channel portion.

### SUMMARY OF THE INVENTION

It is therefore an object of the present invention to provide a method for manufacturing a semiconductor device, in which hydrogen can be effectively supplied to a semiconductor substrate portion without any dependence on layer structure even in the semiconductor device that is further multileveled, and damage near a channel of a transistor can be effectively recovered, and to provide a semiconductor device manufactured by the method thereof.

The method for manufacturing a semiconductor device to attain the above-mentioned object of the present invention is characterized by carrying out the following steps. First, the transistor is formed on the surface region of the semiconductor substrate isolated by an insulating isolation region. Next, an inter-layer insulation film, on which a hydrogen supplying path that reaches the isolation region is placed, is formed on the semiconductor substrate on which the transistor is formed. After that, by carrying out the heat treatment, the hydrogen is supplied to the semiconductor substrate from the hydrogen supplying path through the isolation region.

The above-mentioned manufacturing method forms on the semiconductor substrate the inter-layer insulation film, on which the hydrogen supplying path reaching the isolation region is placed, and then carries out the heat treatment. Consequently, without regard to the layer structure of the inter-layer insulation film, that is, even if the inter-layer insulation film is the thick film constituted by stacked layer structure and even if the barrier film for preventing the hydrogen from being diffused is used inside the inter-layer insulation film, the hydrogen is surely supplied through the hydrogen supplying path and the isolation region to the semiconductor substrate. Also, in this case, since the hydrogen is supplied from the isolation region portion to the semiconductor substrate, the supply of the hydrogen is efficiently performed on the channel portion from the deeper position inside the semiconductor substrate.

Also, the present invention relates to the semiconductor device obtained by the above-mentioned method. A transistor is formed on the surface region of the semiconductor substrate isolated by the isolation region, and the semiconductor substrate on which this transistor is placed is covered by the inter-layer insulation film. And in particular, this is characterized in that the hydrogen supplying path reaching the isolation region is provided in the inter-layer insulation film.

In the semiconductor device having the above-mentioned configuration, for example, by carrying out the heat treatment, the hydrogen is supplied from the hydrogen supplying path provided in the inter-layer insulation film, through the isolation region to the semiconductor substrate. Thus, without any dependence on the film configuration of the inter-layer insulation film, the damage of the semiconductor substrate on which the transistor is formed is recovered by the hydrogen supply.

### EFFECT OF THE INVENTION

As explained above, according to the manufacturing method of the semiconductor device of the present invention and the semiconductor device, without any dependence on the layer structure of the inter-layer insulation film, the hydrogen can be surely supplied to the surface layer of the semiconductor substrate on which the transistor is formed. It is possible to obtain the transistor, in which the property is excellent and the processing damage of the channel portion induced in the manufacturing step is effectively recovered.

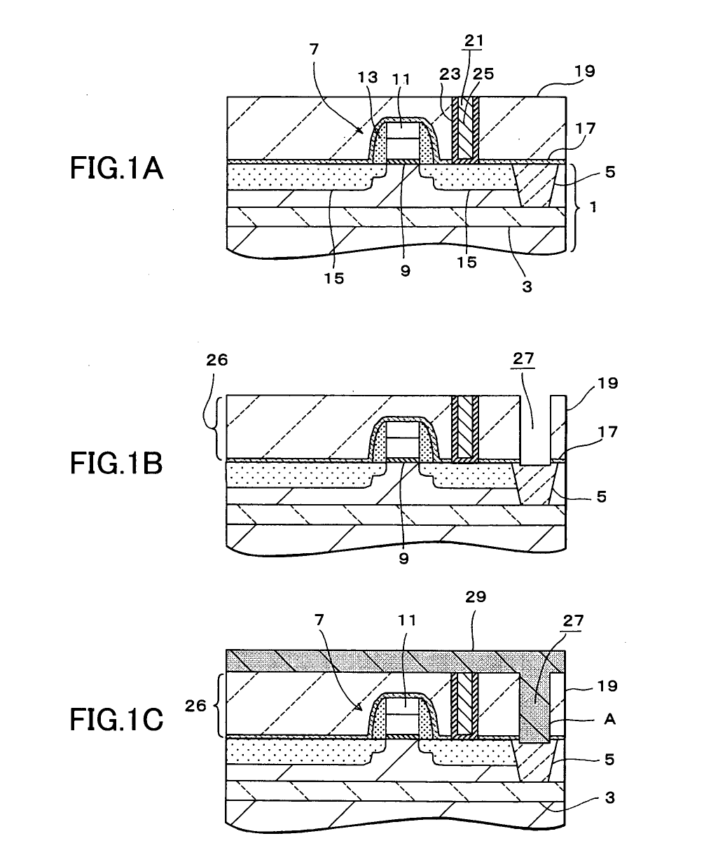

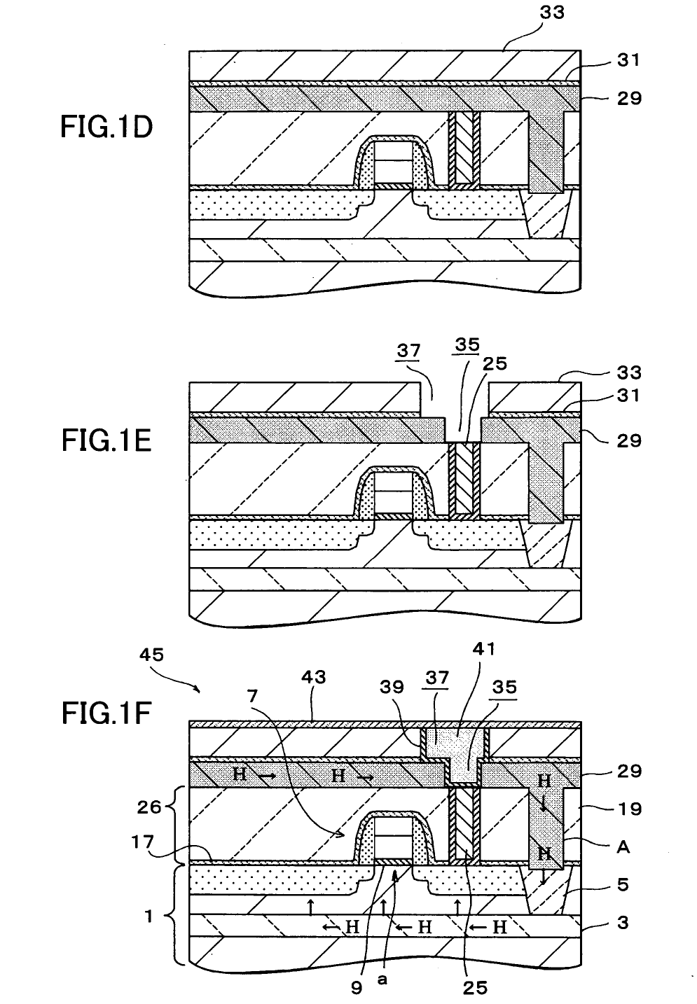

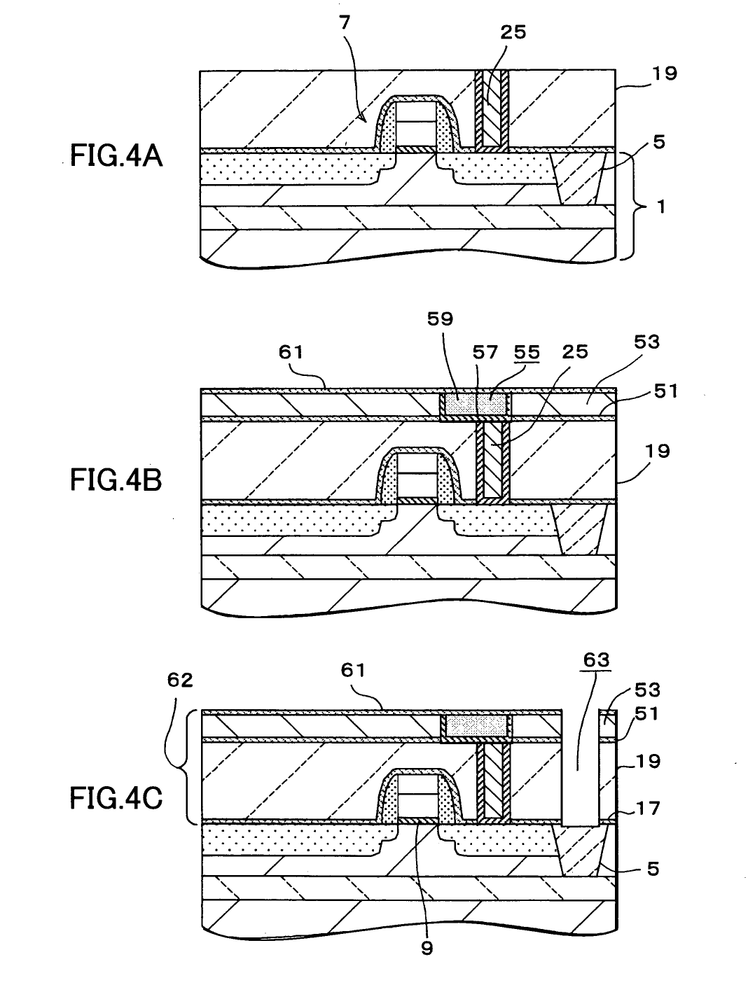

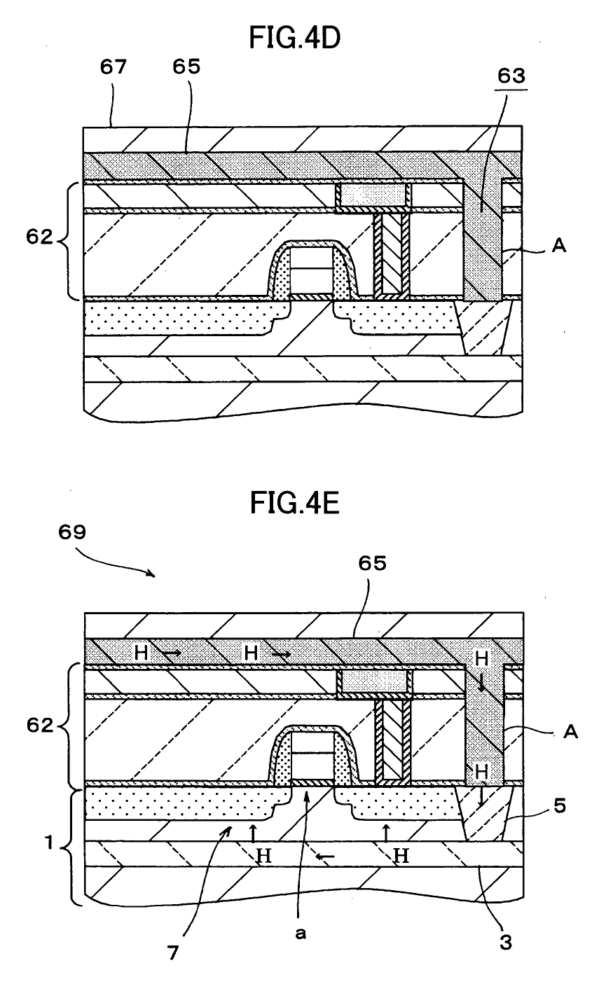

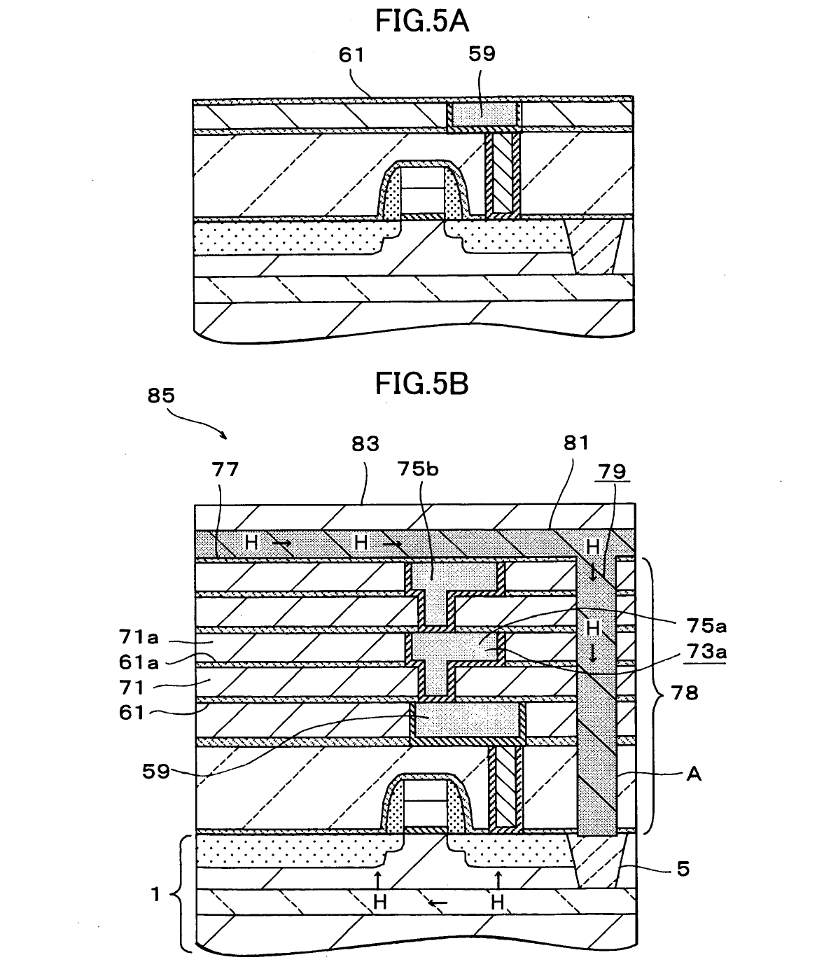

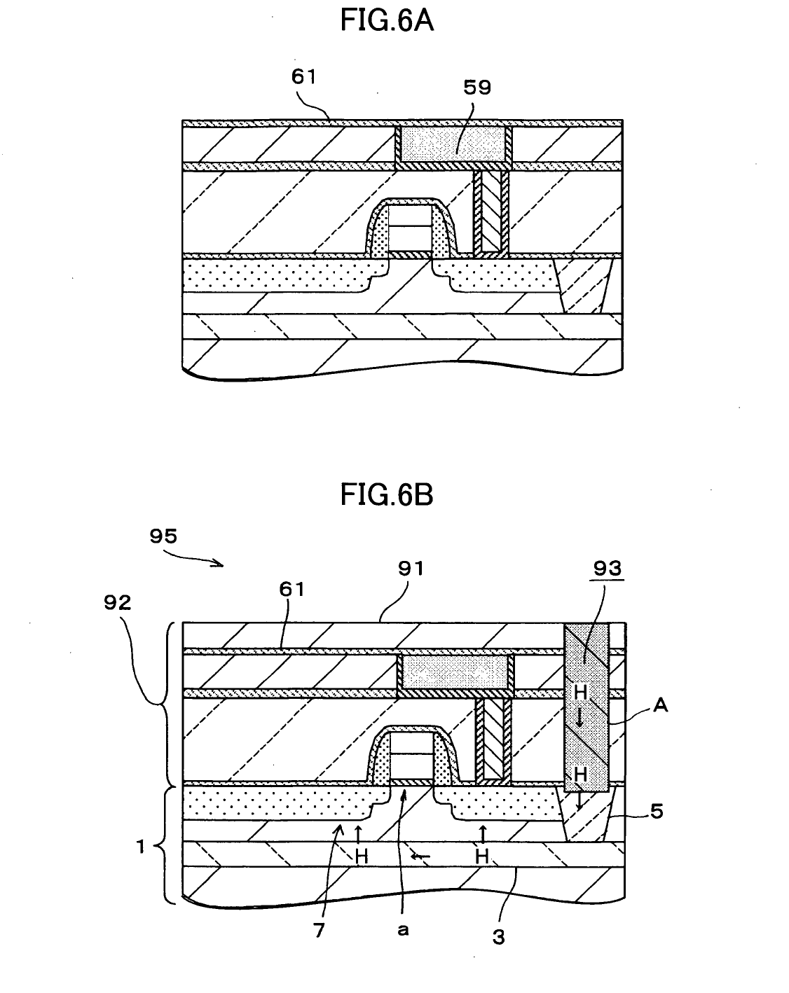

### BRIEF EXPLANATION OF THE DRAWINGS

[FIG. 1A through 1F] are sectional step views showing a manufacturing procedure of a first embodiment.

[FIG. 2] is a graph showing a Vg-Id property of a MOS transistor.

[FIG. 3] is a sectional view showing a variation in the first embodiment.

[FIG. 4A through 4E] are sectional step views showing a manufacturing procedure of a second embodiment.

[FIG. 5A and 5B] are sectional step views showing a manufacturing procedure of a fourth embodiment.

[FIG. 6A and 6B] are sectional step views showing a manufacturing procedure of a fifth embodiment.

### BEST MODE FOR CARRYING OUT THE INVENTION

Embodiments of the present invention will be described below in detail with reference to the drawings. In the respective embodiments, the method for manufacturing the semiconductor device where copper (Cu) interconnect is provide by an embedded interconnect process and the semiconductor device manufactured by the method thereof are explained.

### First Embodiment

FIG. 1A through FIG. 1F are sectional step views showing the first embodiment. The first embodiment of the present invention will be described below on the basis of those drawings.

At first, as shown in FIG. 1A, an SOI substrate 1 is prepared as a semiconductor substrate. This SOI substrate 1 is provided with a silicon oxide film (so-called BOX: buried oxide layer) having a film thickness of 5 nm˜500 nm as an oxide film layer 3 formed in the predetermined depth from the surface. And, on the surface side of the above-mentioned SOI substrate 1, an isolation region 5, namely, STI (Shallow Trench Isolation), which is silicon oxide embedded in the trench, is formed so that it reaches the oxide film layer 3, and the surface side of the SOI substrate 1 is isolated.

Next, a MOS transistor 7 is formed on the surface portion of the SOI substrate 1 isolated by the isolation region 5. This MOS transistor 7 is designed as a MOS transistor, for example, having a LDD structure, and it has a gate electrode 11 defined as two-layer structure over a gate oxide film 9 on the SOI substrate 1. Beside the side wall of the gate electrode 11, there is provide with an insulating sidewall 13. Also, source and drains 15 having LDD are formed on the surface layers of the SOI substrate 1 in both sides of the gate electrode 11. By the way, the gate electrode 11 is defined as two-layer structure in which silicide layers of silicon and metal such as cobalt, nickel or the like are stacked, for example, on the layer configured by using poly-silicon and silicon-germanium (SiGe).

And, an etching stopper layer 17 made of silicon nitride is formed on the SOI substrate 1 on which the above-mentioned isolation region 5 and MOS transistor 7 are formed. Moreover, an inter-layer insulation film 19 made of silicon oxide, for example, such as NSG, BPSG, PSG and the like, are formed on this etching stopper layer 17. By the way, this etching stopper layer 17 also serves as the barrier film for preventing the transmission of hydrogen, as this is made of silicon nitride.

Next, a connection hole 21 is formed through the inter-layer insulation film 19 and the etching stopper layer 17 until the source and drain 15 of the MOS transistor 7 is reached. And, the surface layer of the source and drain 15 exposed at the bottom surface of the connection hole 21 is made silicide by the reaction with cobalt, nickel or the like, to reduce the resistance of it. Moreover, the inner wall of the connection hole 21 is covered with a barrier metal layer 23 made of TiN and the like. After that, a plug 25 made of tungsten (W) and the like is embedded and formed in the connection hole 21 with the barrier metal layer 23 intervening.

The above-mentioned steps are carried out in accordance with the manufacturing procedure of the usual semiconductor device. And, the following steps are specific to this first embodiment.

At first, as shown in FIG. 1B, the inter-layer insulation film 19 and the etching stopper layer 17 are defined as an inter-layer insulation film 26, and a hole 27 which reaches the isolation region 5 is formed in this inter-layer insulation film 26. The formation of this hole 27 is carried out by a photolithography technique to form a resist pattern and then to etch the inter-layer insulation film 19 and the etching stopper layer 17 with the resist pattern as an etching mask.

In succession, as shown in FIG. 1C, a hydrogen containing insulation film 29 made of insulating hydrogen containing material is formed on the inter-layer insulation film 26 so as to embed in the hole 27. Consequently, the hydrogen containing insulation film 29 is formed on the inter-layer insulation film 26, and a hydrogen supplying path A in which the hydrogen containing insulation film 29 is embedded is formed in the hole 27 reaching the isolation region 5. Consequently, the hydrogen supplying path A is formed integrated with the hydrogen containing insulation film 29 on the inter-layer insulation film 26.

When the above-mentioned hydrogen containing insulation film 29 and hydrogen supplying path A are formed, the film is designed to be formed such that the film thickness of the hydrogen containing insulation film 29 on the inter-layer insulation film 26 becomes 50 nm˜500 nm. And, for example, when HSQ (Hydrogen Silisesqui Oxane) is used as a hydrogen containing material, the hydrogen containing insulation film 29 is formed in a condition that it is embedded in the hole 27 by coating. Also, if the aperture of the hole 27 is large, the coating may be done twice. Also, the film thickness of the hydrogen containing insulation film 29 on the inter-layer insulation film 26 may be adjusted by coating one time, and performing etch-back, and then embedding the hydrogen containing material (HSQ)only in the hole 27, and coating again.

By the way, the hydrogen containing material is not limited to the HSQ. In the case of the insulating material containing the hydrogen, it is possible to use silicon nitride film, silicon oxide film, silicon oxide carbide film and organic film. Also, in the case of the material film formed by using a CVD method, the gas containing the hydrogen, such as SiH4-based gas, H2 gas, CHF-based gas and the like, is used as the film forming gas. Then, the hydrogen containing insulation film 29 containing much of hydrogen is formed by adjusting its flow rate. However, in consideration with the formation of copper interconnect performed later, the hydrogen containing insulation film 29 is desired to be made of low dielectric constant material.

Next, as shown in FIG. 1D, on the hydrogen containing insulation film 29, a silicon nitride film and/or a silicon carbide film are formed at film thicknesses of 200 nm˜500 nm as an etching stopper layer 31. Moreover, a low dielectric constant film 33 such as HSQ, SiOC film, carbon film and the like is formed at a film thickness of 200 nm˜500 nm. By the way, instead of the low dielectric constant film 33, the insulation film composed of the silicon oxide film may be formed.

After that, as shown in FIG. 1E, the connection hole 35 which reaches the plug 25 is formed in the low dielectric constant film 33, the etching stopper layer 31 and the hydrogen containing insulation film 29. Next, a interconnect trench 37 is formed so as to encompass the connection hole 35 on the low dielectric constant film 33, and the dual damascene pattern is formed where the connection hole 35 is formed in the bottom portion of the interconnect trench 37. At this time, the etching of the low dielectric constant film 33 is stopped at the etching stopper layer 31.

Next, as shown in FIG. 1F, the interconnect trench 37 and the inner wall of the connection hole 35 are covered with a barrier metal 39, and a copper interconnect 41 is embedded and formed in the connection hole 35 with the barrier metal 39 intervening. After that, while the copper interconnect 41 is covered by it, an etching stopper layer 43 made of silicon nitride is formed, which also has a function of preventing the diffusion of copper. Also, although the illustration is omitted here, a film forming step and a patterning step and the like are further performed as necessary. Finally, a cover film which is made of, for example, SiN and the like is formed.

After the above-mentioned steps, by carrying out the heat treatment, a hydrogenating process is carried out for supplying hydrogen in the hydrogen containing insulation film 29 through the hydrogen supplying path A to the isolation region 5 made of the silicon oxide to the oxide film layer 3 to the surface layer of the SOI substrate 1. Consequently, the dangling bond of the silicon in a channel portion a of the transistor 7 formed on the surface side of the SOI substrate 1 is hydrogen-terminated, and the damage induced in the process is recovered to then complete a semiconductor device 45.

The semiconductor device 45 formed as mentioned above is such that the hydrogen supplying path A reaching the isolation region 5 is placed in the inter-layer insulation film 26 covering the SOI substrate 1 on which the transistor 7 is formed. Also, the hydrogen supplying path A is configured such that the hydrogen containing material is embedded in the hole 25 and such that it reaches the hydrogen containing insulation film 29 formed on the inter-layer insulation film 26. Moreover, the hydrogen supplying path A is placed so as to reach the buried oxide film layer 3 formed at the inner portion of the SOI substrate 1 through the isolation region 5.

And, according to the manufacturing method of the semiconductor device as mentioned above, as explained by using FIG. 1F, by carrying out the heat treatment in the condition that on the inter-layer insulation film 26 covering the SOI substrate 1, the hydrogen supplying path A reaching the isolation region 5 is formed and the hydrogen containing insulation film 29 reaching the hydrogen supplying path A is further formed on the inter-layer insulation film 26, the hydrogenating process is carried out for supplying the hydrogen in the hydrogen containing insulation film 29 through the hydrogen supplying path A to the isolation region 5 made of the silicon oxide to the oxide film layer 3 to the surface layer of the SOI substrate 1. Due to this, without any dependence on the structure of the inter-layer insulation film 26 in the lower layer of the hydrogen containing insulation film 29, the hydrogen can be supplied from the buried oxide film layer 3 formed at the inner portion of the the SOI substrate 1 to the channel portion a of the transistor 7. In short, the etching stopper layer 17 of the silicon nitride serving as the barrier layer for preventing the transmission of the hydrogen is formed on the SOI substrate 1. However, even if the above-mentioned barrier layer exists, the hydrogen can be surely supplied into the SOI substrate 1. Moreover, due to the hydrogen supply through the oxide film layer 3 and the isolation region 5 formed on the surface side of the SOI substrate 1, the hydrogen is supplied from inside the SOI substrate 1.

As a result, the hydrogen supply is more efficiently performed on the channel portion a. Thus, it is possible to obtain the transistor having the excellent property in which the processing damage of the channel portion induced in the manufacturing step is effectively recovered.

Also in particular, as for the hydrogen supply to the surface layer of the SOI substrate 1, the hydrogen H is supplied from the oxide film layer 3 which is arranged entirely below the transistor 7. Thus, the hydrogen can be supplied to the whole of the channel portion a efficiently and uniformly, thereby obtaining the above-mentioned effects more efficiently.

Moreover, after the plug 25 having the silicide process whose processing temperature is high and the like is formed, the hydrogen containing insulation film 29 and the hydrogen supplying path A are formed. This can prevent the hydrogen from being dissociated from the hydrogen containing insulation film 29 and the hydrogen supplying path A, prior to the execution of the hydrogenating process. Thus, at the time of the hydrogenating process, the hydrogen can be sufficiently supplied from the hydrogen containing insulation film 29 and the hydrogen supplying path A.

Moreover, when the hydrogen containing insulation film 29 and the hydrogen supplying path A are made of the silicon oxide based material such as the HSQ and the like, the hydrogen contained in them and the hydrogen contained in the oxide film layer 3 and isolation region 5 which are made of the silicon oxide are isolated even at the low temperature of 400° C. or less. This enables the hydrogenating process (the hydrogen supply to the channel portion a) at the lower temperature. Consequently, it is possible to prevent the occurrence of the defect of the copper interconnect 41 already formed at the time of the hydrogenating process and the like.

And, since the hydrogen is supplied from the isolation region 5 and the oxide film layer 3, the hydrogen is supplied from the position which is kept at a certain distance with respect to the channel portion a, and the excessive supply of the hydrogen to the channel portion a is prevented. Thus, the interface state between the channel portion and the gate insulation film can be kept low.

FIG. 2 shows the gate voltage (Vg)-drain current (Id) property in the MOS transistor. As mentioned above, since the excessive supply of the hydrogen to the channel portion a is prevented to keep the interface state of the channel portion low, as shown in the graph of FIG. 2, the drain current (Id) can be sufficiently reduced in the region in which the gate voltage (Vg) is low. And, the leak (off leak) of the drain current (Id) can be suppressed. On the contrary, if the hydrogen is excessively supplied to the channel portion a, as shown in the dashed line of FIG. 2, it is difficult to reduce the drain current (Id) in the region in which the gate voltage (Vg) is low. Thus, the problem such as the increase in the leak (off leak) of the drain current (Id) is induced.

By the way, in this first embodiment, the manufacturing of the semiconductor device 45 having the configuration in which the MOS transistor 7 is formed on the surface side of the SOI substrate 1 is explained. However, the present invention can be applied to even the manufacturing method of the semiconductor device having the configuration in which the MOS transistor 7 is formed on the surface side of a semiconductor substrate 1′ as so-called bulk, and the similar procedure is performed. However, in this case, in the semiconductor substrate 1′, there is not the layer corresponding to the oxide film layer (3) in the SOI substrate (1). For this reason, in the step of the hydrogenating process explained by using FIG. 1F in the first embodiment, the hydrogen H can be diffused into the channel portion a from inside the semiconductor substrate 1′ through the isolation region 5 from the hydrogen containing insulation film 29.

### Second Embodiment

FIG. 4A through FIG. 4E are sectional step views showing the second embodiment. The second embodiment of the present invention will be described below in accordance with those drawings.

At first, the step shown in FIG. 4A is carried out similarly to the case explained by using FIG. 1A in the first embodiment, and the isolation region 5, the transistor 7, the inter-layer insulation film 19 and the plug 25 are formed on the surface side of the SOI substrate 1.

Next, as shown in FIG. 4B, on the inter-layer insulation film 19, an etching stopper layer 51 made of silicon nitride is formed, and a low dielectric constant film 53 (even silicon oxide film is allowable) is further formed. And, a interconnect trench 55 to which the upper surface of the plug 25 is exposed is formed on those low dielectric constant film 53 and etching stopper layer 51, and a copper interconnect 59 is embedded and formed in this interconnect trench 55 with a barrier metal layer 57 intervening. After that, in a condition that the copper interconnect 59 is covered, an etching stopper layer 61 made of silicon nitride is formed on the low dielectric constant film 53.

And, as shown in FIG. 4C, the insulation film of the layer lower than the etching stopper layer 61 formed on the SOI substrate 1 is defined as an inter-layer insulation film 62, and a hole 63 which reaches the isolation region 5 is formed on this inter-layer insulation film 62. The formation of this hole 63 is carried out by using the photolithography technique to form the resist pattern and then to etch the inter-layer insulation film 62 with the resist pattern as the mask.

After that, as shown in FIG. 4D, so as to embed in the hole 63, a hydrogen containing insulation film 65 made of insulating hydrogen containing material is formed on the inter-layer insulation film 62. The formation of this hydrogen containing insulation film 65 is carried out similarly to the case explained by using FIG. 1C in the first embodiment. Next, a cover film 67 made of SiON and the like is formed on the hydrogen containing insulation film 65.

Under this condition, as shown in FIG. 4E, by carrying out the heat treatment, the hydrogenating process is carried out for supplying the hydrogen in the hydrogen containing insulation film 65 through the hydrogen supplying path A to the isolation region 5 made of the silicon oxide to the oxide film layer 3 to the surface layer of the SOI substrate 1. Consequently, the dangling bond of the silicon in the channel portion a of the transistor 7 formed on the surface side of the SOI substrate 1 is hydrogen-terminated, and the damage induced in the process is recovered to then complete a semiconductor device 69.

The semiconductor device 69 formed as mentioned above is such that the hydrogen supplying path A reaching the isolation region 5 is placed in the inter-layer insulation film 62 covering the SOI substrate 1 on which the transistor 7 is formed. Also, the hydrogen supplying path A is configured such that the hydrogen containing material is embedded in the hole 63 and such that it reaches the hydrogen containing insulation film 65 formed on the inter-layer insulation film 62. Moreover, the hydrogen supplying path A is placed so as to reach the buried oxide film layer 3 formed at the inner portion of the SOI substrate 1 through the isolation region 5.

Even in the manufacturing method of the second embodiment as mentioned above, as explained by using FIG. 4E, by carrying out the heat treatment in the condition that on the inter-layer insulation film 62 covering the SOI substrate 1, the hydrogen supplying path A reaching the isolation region 5 is formed and the hydrogen containing insulation film 65 reaching the hydrogen supplying path A is further formed on the inter-layer insulation film 62, the hydrogenating process is carried out for supplying the hydrogen H in the hydrogen containing insulation film 65 through the hydrogen supplying path A to the isolation region 5 made of the silicon oxide to the oxide film layer 3 to the surface layer of the SOI substrate 1. Thus, the effect similar to the first embodiment can be obtained.

And in particular, in this second embodiment, just before the step of forming the cover film 67, namely, just before the final step, the formations of the hydrogen containing insulation film 65 and hydrogen supplying path A are carried out. Thus, at the steps until the subsequent hydrogenating process, the separation or dissociation of the hydrogen from the hydrogen containing insulation film 65 and hydrogen supplying path A is prevented. Hence, at the step of the hydrogenating process, the hydrogen can be supplied to the surface layer of the SOI substrate 1, from the hydrogen containing insulation film 65 and hydrogen supplying path A in which the hydrogen is sufficiently contained, and the recovering force of the damage (the hydrogen terminating force) can be maintained.

Also, this second embodiment can be applied to even the manufacturing method of the semiconductor device having the configuration in which the MOS transistor 7 is formed on the surface side of the semiconductor substrate as the so-called bulk, and the similar procedure is performed.

### Third Embodiment

FIGS. 5A and 7B are sectional step views showing the third embodiment. The third embodiment of the present invention will be described below on the basis of those drawings.

This third one is the embodiment in which the semiconductor device where interconnect structure is further multileveled, according to the manufacturing method of the semiconductor device explained in the second embodiment,

At first, the steps shown until FIG. 5A are carried out similarly to the steps explained until FIG. 4B in the second embodiment, and an etching stopper layer 61 for covering a copper interconnect 59 is formed.

After that, as shown in FIG. 5B, on the etching stopper layer 61, a low dielectric constant film 71, an etching stopper layer 61a and a low dielectric constant film 71a are formed in this order, and a trench 73a of dual damascene structure composed of a interconnect trench and a connection hole reaching a copper interconnect (a first copper interconnect 59) is formed in those films, and a second copper interconnect 75a is formed. The formations of those trench 73a and second copper interconnect 75a are carried out similarly to the formation of the copper interconnect (41) explained by using FIG. 1F.

Also, depending on necessity, the similar steps are performed on the low dielectric constant film 71a. Furthermore, after a third copper interconnect 75b and a copper interconnect on the higher layer are formed, in a condition that the copper interconnect (for example, the third copper interconnect 75b) on the uppermost layer is covered, an etching stopper layer 77 is formed on the low dielectric constant film. And, this etching stopper layer 77 and the film of the lower layer are defined as an inter-layer insulation film 78, and a hole 79 which reaches the isolation region 5 is formed in this inter-layer insulation film 78. Next, so as to embed in the hole 79, a hydrogen containing insulation film 81 made of insulating hydrogen containing material is formed on the inter-layer insulation film 78. The formation of this hydrogen containing insulation film 81 is carried out similarly to the case explained by using FIG. 1C in the first embodiment. Next, a cover film 83 made of SiON and the like is formed on the hydrogen containing insulation film 81.

Under this condition, by carrying out the heat treatment, the hydrogenating process is carried out for supplying the hydrogen H in the hydrogen containing insulation film 81 through the hydrogen supplying path A to the isolation region 5 made of the silicon oxide to the oxide film layer 3 to the surface layer of the SOI substrate 1. Consequently, the dangling bond of the silicon in the channel portion a of the transistor 7 formed on the surface side of the SOI substrate 1 is hydrogen-terminated, and the damage induced in the process is recovered to then complete a semiconductor device 85.

The semiconductor device 85 formed as mentioned above is such that the hydrogen supplying path A reaching the isolation region 5 is placed in the inter-layer insulation film 78 covering the SOI substrate 1 on which the transistor 7 is formed. Also, the hydrogen supplying path A is configured such that the hydrogen containing material is embedded in the hole 79 and such that it reaches the hydrogen containing insulation film 65 formed on the inter-layer insulation film 78. Moreover, the hydrogen supplying path A is placed so as to reach the buried oxide film layer 3 formed at the inner portion of the SOI substrate 1 through the isolation region 5.

Even in the manufacturing method of the third embodiment as mentioned above, by carrying out the heat treatment in the condition that on the inter-layer insulation film 78 covering the SOI substrate 1, the hydrogen supplying path A reaching the isolation region 5 is formed and the hydrogen containing insulation film 81 reaching the hydrogen supplying path A is further formed on the inter-layer insulation film 78, the hydrogenating process is carried out for supplying the hydrogen H in the hydrogen containing insulation film 81 through the hydrogen supplying path A to the isolation region 5 made of the silicon oxide to the oxide film layer 3 to the surface layer of the SOI substrate 1. Thus, in particular, due to the formations of the multileveled copper interconnects 59, 75a and 75b, even in the case of the lamination of the etching stopper layers 61, 61a, . . . of the silicon nitride serving as the barrier layer, since the hydrogen supplying path A is placed in the inter-layer insulation film 78 including those etching stopper layers 61, 61a, . . . , the effect similar to the first embodiment can be obtained independently of the film configuration of the inter-layer insulation film 78.

Also in particular, since the hydrogen containing insulation film 81 and the hydrogen supplying path A are made of the silicon oxide based material such as the HSQ and the like, the hydrogenating process at the low temperature is possible as explained in the first embodiment. Thus, without any damage to all of those copper interconnects 59, 75a and 75b, the above-mentioned effect can be obtained.

Also, this third embodiment can be applied to even the manufacturing method of the semiconductor device having the configuration in which the MOS transistor 7 is formed on the surface side of the semiconductor substrate as the so-called bulk, such as the silicon substrate and the like, similarly to the first embodiment, and the similar procedure is performed.

### Fourth Embodiment

FIGS. 6A and 8B are sectional step views showing the fourth embodiment. The fourth embodiment of the present invention will be described below in accordance with those drawings.

The difference between this fourth embodiment and the other embodiments lies in that the hydrogen containing insulation film linking to the hydrogen supplying path is not formation, and the following procedure is carried out.

At first, as shown in FIG. 8(a), it is carried out similarly to the case explained by using FIG. 4B in the second embodiment, and the etching stopper layer 61 for covering the copper interconnect 59 is formed.

After that, as shown in FIG. 8(b), an insulation film 91 is formed on the etching stopper layer 61, and this insulation film 91 and the film of the layer lower than this are defined as an inter-layer insulation film 92, and a hole 63 which reaches the isolation region 5 is formed in this inter-layer insulation film 92. Next, the insulating hydrogen containing material is embedded in the hole 93, and the hydrogen supplying path A reaching the isolation region 5 is formed. At this time, after the hydrogen containing insulation film is formed on the inter-layer insulation film 92 in the condition that it is embedded in the hole 93, so as to leave the hydrogen containing insulation film only in the hole 93, the hydrogen containing insulation film on the inter-layer insulation film 92 is removed, thereby forming the hydrogen supplying path A in which the hydrogen containing material is embedded in the hole 93.

Under this condition, by carrying out the heat treatment in hydrogen containing gas atmosphere, the hydrogenating process is carried out for supplying the hydrogen H in the hydrogen containing atmosphere through the hydrogen supplying path A to the isolation region 5 made of the silicon oxide to the oxide film layer 3 to the surface layer of the SOI substrate 1. Consequently, the dangling bond of the silicon in the channel portion a of the transistor 7 formed on the surface side of the SOI substrate 1 is hydrogen-terminated, and the damage induced in the process is recovered to then complete a semiconductor device 95.

The semiconductor device 95 formed as mentioned above is such that the hydrogen supplying path A reaching the isolation region 5 is placed in the inter-layer insulation film 92 covering the SOI substrate 1 on which the transistor 7 is formed. Also, the hydrogen supplying path A is placed such that the hydrogen containing material is embedded in the hole 63 and it reaches the buried oxide film layer 3 formed at the inner portion of the SOI substrate 1 through the isolation region 5.

Even in the manufacturing method of the fourth embodiment as mentioned above, as explained by using FIG. 8(b), the hydrogenating process is carried out for supplying the hydrogen H in the hydrogen containing atmosphere through the hydrogen supplying path A to the isolation region 5 made of the silicon oxide to the oxide film layer 3 to the surface layer of the SOI substrate 1. Thus, the effect similar to the first embodiment can be obtained.

Also, this fourth embodiment can be applied to even the manufacturing method of the semiconductor device having the configuration in which the MOS transistor 7 is formed on the surface side of the semiconductor substrate as the so-called bulk, such as the silicon substrate and the like, similarly to the first embodiment, and the similar procedure is performed.

By the way, in the above-mentioned first to fourth embodiments, the configuration of placing the hydrogen supplying path A in which the hydrogen containing material is embedded in the hole formed in the inter-layer insulation film is explained. However, the hydrogen supplying path of the present invention is not limited to the above-mentioned implementation. For example, when the inter-layer insulation film is composed of a barrier layer for preventing the transmission of the hydrogen and a material layer through which the hydrogen is transmitted, the formation of an opening in the barrier layer portion on the isolation region causes the hydrogen to be supplied through this opening to the isolation region. Thus, this may be defined as the hydrogen supplying path reaching the isolation region.

1. A method for manufacturing a semiconductor device, said method comprising the steps of:
forming a transistor on a surface region of a semiconductor substrate which is isolated by an insulating isolation region;
forming an inter-layer insulation film provide with a hydrogen supplying path that reaches said isolation region on said semiconductor substrate on which said transistor is formed; and
supplying hydrogen in said semiconductor substrate from said hydrogen supplying path through said isolation region by carrying out heat treatment.

2. A method for manufacturing a semiconductor device according to claim 1, wherein said step of forming said inter-layer insulation film provided with said hydrogen supplying path includes:
forming a hole in said insulating layer which reaches said isolation region after forming said insulating film on said semiconductor substrate, and
forming a hydrogen supplying path by embedding a hydrogen containing material in said hole.

3. A method for manufacturing a semiconductor device according to claim 1, wherein a step of forming a hydrogen containing insulating film on said inter-layer insulation film is performed between said step of forming said inter-layer insulation film and said step of supplying hydrogen.

4. A method for manufacturing a semiconductor device according to claim 1, wherein said step of supplying hydrogen supplies hydrogen from said hydrogen supplying path through said isolation region to a buried oxide layer provide at the inner portion of said semiconductor substrate, and to said surface side of said semiconductor substrate from said oxide layer.

5. A method for manufacturing a semiconductor device according to claim 1, wherein said step of forming said inter-layer insulation film forms a contact hole which reaches said transistor at least in the lower layer of said inter-layer insulation films and forms in said hole a plug which is connected to said transistor.

6. A method for manufacturing a semiconductor device according to claim 5, wherein said step of forming said inter-layer insulation film forms in a middle layer of said inter-layer insulation film an interconnect pattern which is connected to said plug.

7. A method for manufacturing a semiconductor device according to claim 1, wherein said step of forming said inter-layer insulation film stacks a barrier layer which prevents the diffusion of hydrogen, and another layer

8. A method for manufacturing a semiconductor device according to claim 7, wherein said step of forming said inter-layer insulation film includes the step of:
forming an opening in said barrier layer on said isolation region in order to form said hydrogen supplying path.

9. A semiconductor device having an isolation region provided on a surface side of a semiconductor substrate, a transistor provided on a surface region of said semiconductor substrate isolated by said isolation region, and an inter-layer insulation film covering over said semiconductor substrate provided with said transistor, wherein:
said inter-layer insulation film is provided with a hydrogen supplying path which reaches said isolation region.

10. A semiconductor device according to claim 9, wherein:
said hydrogen supplying path is configured by embedding a hydrogen containing material in a hole formed in said inter-layer insulation film.

11. A semiconductor device according to claim 9, wherein:
said hydrogen supplying path reaches a hydrogen containing insulation film formed on said inter-layer insulation film.

12. A semiconductor device according to claim 9, wherein:
a buried oxide layer is provided at the inner portion of said semiconductor substrate and said isolation region reaches said oxide layer.

13. A semiconductor device according to claim 9, wherein:
a contact hole which reaches said transistor is formed at least in the lower layer of said inter-layer insulation film and a plug which is connected to said transistor is formed in said contact hole.

14. A semiconductor device according to claim 13, wherein:
an interconnect pattern which is connected to said plug is formed in a middle layer of said inter-layer insulation film.

15. A semiconductor device according to claim 9, wherein:
said inter-layer insulation film is formed of a stacked structure having a barrier layer which prevents the diffusion of hydrogen, and another layer stacked.

16. A semiconductor device according to claim 15, wherein:
said hydrogen supplying path is an opening formed in said barrier layer.
